(19) United States
(12) Patent Application Publication
(10) Pub. No.: US 2025/0033893 A1
(43) Pub. Date: Jan. 30, 2025

(54) Article Transferrer

(71) Applicant: Daifuku Co., Ltd., Osaka-shi (JP)

(72) Inventor: Hiroshi Otsuka, Hinocho (JP)

(21) Appl. No.: 18/785,088

(22) Filed: Jul. 26, 2024

(30) Foreign Application Priority Data
Jul. 28, 2023 (JP) 2023-123389

(51) Int. Cl. B65G 43/08; B65G 35/06; B65G 47/90

(52) U.S. Cl. CPC B65G 43/08; B65G 35/06; B65G 47/905; B65G 2203/0233; B65G 2203/0258

(57) ABSTRACT

An article transferrer includes a holder that holds an article, an advancement-retraction driver that advances and retracts the holder, and a controller that controls the advancement-retraction driver. The controller controls the advancement-retraction driver based on an output command value in an advancement and retraction operation of advancing or retracting the holder by the advancement-retraction driver. The output command value is determined based on a reference command pattern being a time-varying pattern of command values indicating positions, speed, or acceleration which time-varying pattern involves a stepwise acceleration change over time. The output command value is a moving average, within a predetermined period, of the command values indicated by the reference command pattern.

### CROSS-REFERENCE TO RELATED APPLICATION

This application claims priority to Japanese Patent Application No. 2023-123389 filed Jul. 28, 2023, the disclosure of which is hereby incorporated by reference in its entirety.

### BACKGROUND OF THE INVENTION

### Field of the Invention

The present invention relates to an article transferrer including a holder that holds an article, an advancement-retraction driver that advances and retracts the holder, and a controller that controls the advancement-retraction driver.

### Description of Related Art

An example of such an article transferrer is described in Japanese Unexamined Patent Application Publication No. 2007-119136 (Patent Literature 1). In the background described hereafter, reference signs in parentheses are the reference signs in Patent Literature 1. An article transferrer (13) in Patent Literature 1 includes a fork (24) that holds an article (9), an advancement-retraction drive (25) that advances and retracts the fork (24) between a retracted position and an advancement position, and an advancement-retraction controller (31c) that controls the advancement-retraction drive (25). To advance the fork (24) from the retracted position to the advancement position or to retract the fork (24) from the advancement position to the retracted position, the advancement-retraction controller (31c) controls the speed of advancing and retracting the fork (24) based on an advancement and retraction speed curve shown in FIG. 6 in Patent Literature 1.

In advancing and retracting a holder (the fork in Patent Literature 1), the holder or an article held by the holder may vibrate as the acceleration of the holder changes. The vibration of the holder or the article held by the holder may delay a subsequent operation (e.g., a lifting and lowering operation of the holder) until the vibration stops, or may adversely affect the article. Such vibration is thus to be minimized.

### SUMMARY OF THE INVENTION

Techniques are awaited for easily reducing the vibration of the holder or an article held by the holder due to an advancement and retraction operation of the holder.

An article transferrer according to an aspect of the disclosure includes a holder that holds an article, an advancement-retraction driver that advances and retracts the holder, and a controller that controls the advancement-retraction driver. The controller controls the advancement-retraction driver based on an output command value in an advancement and retraction operation of advancing or retracting the holder by the advancement-retraction driver. The output command value is determined based on a reference command pattern being a time-varying pattern of command values indicating positions, speed, or acceleration which time-varying pattern involves a stepwise acceleration change over time. The output command value is a moving average, within a predetermined period, of the command values indicated by the reference command pattern.

This structure can reduce the change of acceleration (jerk) of the holder in the advancement and retraction operation of the holder compared with a structure that controls the advancement-retraction driver based on the command values indicated by the reference command pattern. This can reduce the change of acceleration acting on the article held by the holder. This structure can thus easily reduce the vibration of the holder or the article held by the holder due to the advancement and retraction operation of the holder.

Further aspects and features of the article transferrer will be apparent from embodiments described below with reference to the drawings.

### BRIEF DESCRIPTION OF THE DRAWINGS

FIG. 1 is a perspective view of a transport vehicle according to an embodiment.

FIG. 2 is a side view of the transport vehicle according to the embodiment.

FIG. 3 is a front view of the transport vehicle according to the embodiment.

FIG. 4 is a control block diagram in the embodiment.

FIG. 5 is a graph showing an example reference command pattern and an example pattern resulting from a sinusoidal process.

FIG. 6 is a diagram showing a reference command pattern and a pattern resulting from a moving average process.

FIG. 7 is a perspective view of a transport vehicle in another embodiment.

### DESCRIPTION OF THE INVENTION

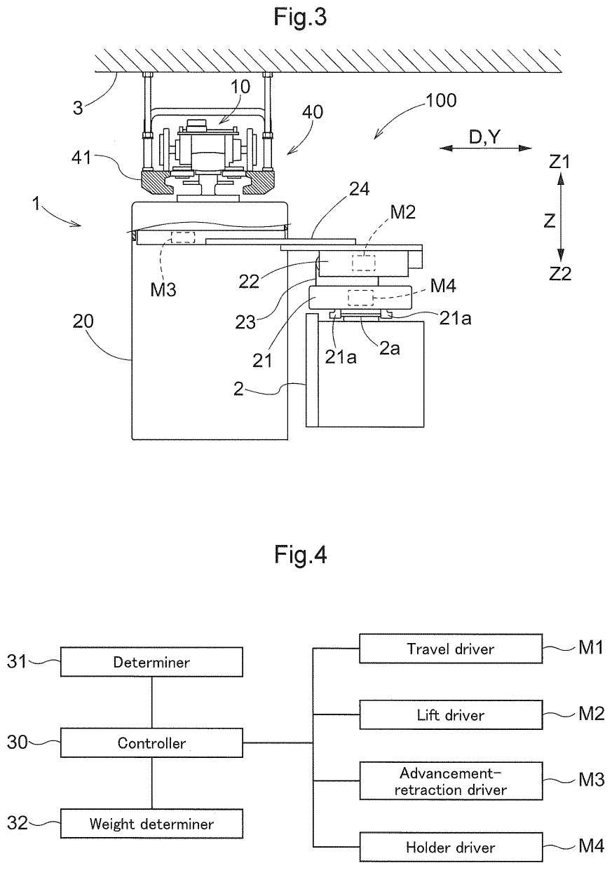

An article transferrer according to an embodiment will be described with reference to the drawings. In the present embodiment, an article transferrer 1 is included in a transport vehicle 100 (automatic guided vehicle in this example) that transports articles 2 as shown in FIGS. 2 and 3. The articles 2 are, for example, front opening unified pods (FOUPs) that contain semiconductor wafers.

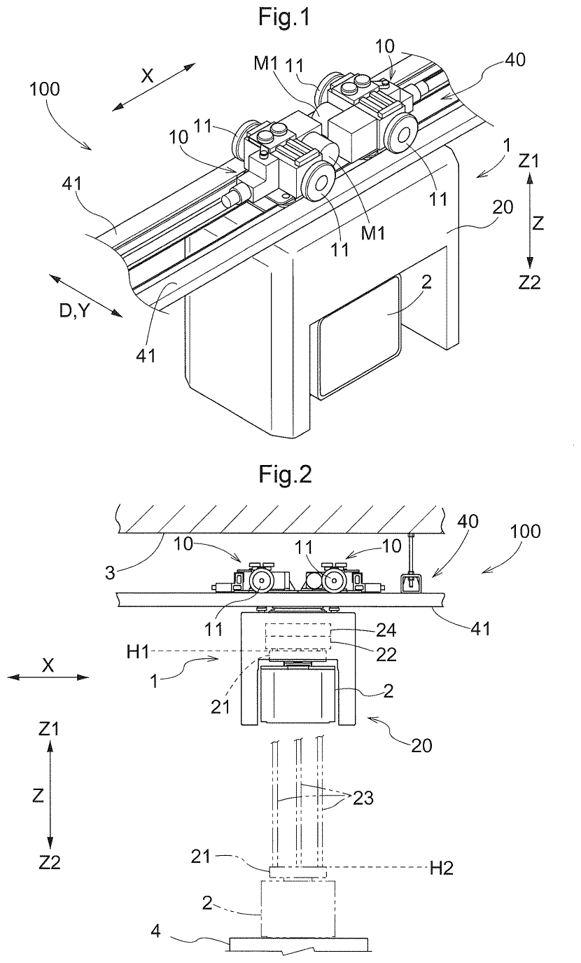

The transport vehicle 100 in the present embodiment shown in FIGS. 1 to 3 has the structure below. The transport vehicle 100 includes a traveler 10 that travels along a travel path 40 and a body 20 connected to the traveler 10. In this example, the body 20 disposed in a lower direction Z2 below the traveler 10 is supported by the traveler 10. An article 2 is accommodated in the body 20 and transported by the transport vehicle 100.

The travel path 40 includes travel rails 41 (a pair of travel rails 41 spaced in a width direction Y in this example). The direction along the travel path 40 is referred to as a travel direction X. The width direction Y is perpendicular to the travel direction X as viewed in a vertical direction Z (the vertical direction), or a horizontal direction perpendicular to the travel direction X in this example. The traveler 10 includes travel wheels 11 that roll on travel surfaces (upper surfaces in this example) of the travel rails 41. The travel wheels 11 are driven by a travel driver M1 (e.g., an electric motor such as a servomotor) to rotate, causing the traveler 10 to travel along the travel rails 41. In this example, the travel rails 41 are hung from a ceiling 3, and the travel path 40 is defined along the ceiling 3. In other words, the transport vehicle 100 in the present embodiment is a ceiling-hung transport vehicle.

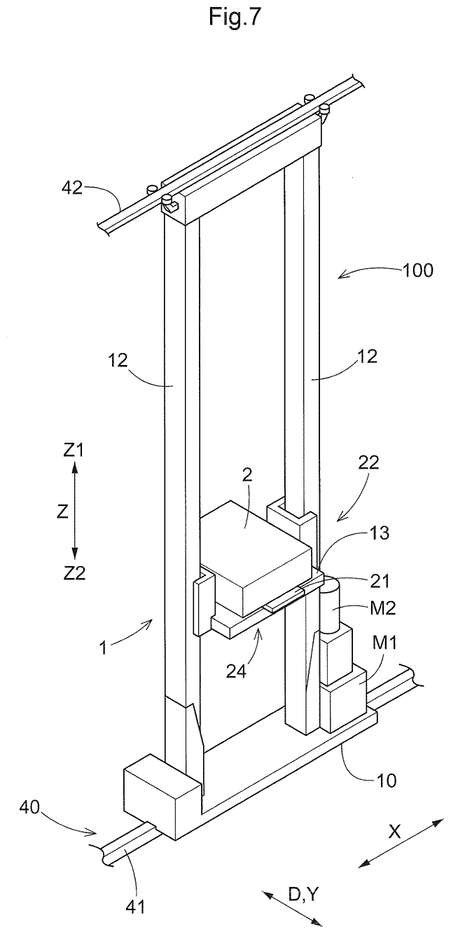

As shown in FIGS. 2 and 3, the article transferrer 1 includes a holder 21 that holds an article 2. In the present embodiment, the holder 21 in an upper direction Z1 holds an article 2. In the example shown in FIG. 3, the holder 21 holds the article 2 with its supports 21a supporting a supportable portion 2a (a flange in this example) disposed above the article 2. The holder 21 may hold an article 2 in any manner. For example, the holder 21 in the lower direction Z2 may hold an article 2 as in the example shown in FIG. 7 (referred to later), or the holder 21 may clamp both sides of an article 2 in the horizontal direction.

In the present embodiment, the holder 21 performs a holding operation of holding an article 2 and a releasing operation of releasing an article 2. In the example shown in FIG. 3, in the holding operation performed by the holder 21, at least parts of the supports 21a are moved lower than the supportable portion 2a in the lower direction Z2. The holder 21 is thus ready to hold an article 2 (or more specifically, the supports 21a are ready to support the supportable portion 2a). In the releasing operation performed by the holder 21, the supports 21a are retracted from the positions below the supportable portion 2a in the lower direction Z2.

The article transferrer 1 includes a holder driver M4 (e.g., an electric motor such as a servomotor) that drives the holder 21 (more specifically, the supports 21a). The holder driver M4 drives the holder 21 to perform the holding operation and the releasing operation. In the example shown in FIG. 3, the holder 21 includes a pair of supports 21a, and the holder driver M4 moves the pair of supports 21a closer to each other or away from each other. In the holding operation performed by the holder 21, each support 21a of the pair is at least partially moved lower than the supportable portion 2a in the lower direction Z2. In the releasing operation performed by the holder 21, each support 21a of the pair is retracted from a position below the supportable portion 2a in the lower direction Z2.

In the example shown in FIG. 3, the holder 21 performs the holding operation by moving the pair of supports 21a closer to each other and the releasing operation by moving the pair of supports 21a away from each other. In another structure, the holder 21 may perform the holding operation by moving the pair of supports 21a away from each other and the releasing operation by moving the pair of supports 21a closer to each other.

In the present embodiment, the article transferrer 1 includes a lift driver M2 (e.g., an electric motor such as a servomotor) that lifts and lowers the holder 21. To lift and lower herein refers to lifting and lowering an object relative to a portion (hereafter referred to as a reference portion) that serves as a reference in the article transferrer 1. In the present embodiment, the reference portion in the article transferrer 1 is a portion of the article transferrer 1 fixed to the body 20. The lift driver M2 thus lifts and lowers the holder 21 relative to the body 20.

The article transferrer 1 includes a lifter 22 that lifts and lowers the holder 21. The lift driver M2 activates the lifter 22 to lift and lower the holder 21. In the example shown in FIG. 2, the lifter 22 winds elongated members 23 (e.g., belts or wires) suspending the holder 21 to lift the holder 21 and unwinds the elongated members 23 to lower the holder 21. Each elongated member 23 has a first end connected to the holder 21 and a second end fixed to a drum (not shown). The lift driver M2 rotates the drum in a first rotation direction to wind the elongated members 23 around the drum and in a second rotation direction to unwind the elongated members 23 from the drum.

When the transport vehicle 100 travels along the travel path 40, the holder 21 is at a reference height H1 (refer to FIG. 2). The reference height H1 is, for example, an upper limit position of a range in which the lifter 22 lifts and lowers the holder 21 (in other words, the height with the elongated members 23 being fully winded). In the example shown in FIG. 2, the body 20 accommodates the holder 21 and an article 2 held by the holder 21 at the reference height H1.

When the transport vehicle 100 (more specifically, the article transferrer 1) transfers an article 2 between the holder 21 and a transfer area 4, the holder 21 is at a transfer height H2 (refer to FIG. 2) corresponding to the transfer area 4. The transfer area 4 is, for example, a load port of a processing device that processes the article 2 (or an object contained in the article 2), a loading and unloading port of a storage device for storing the article 2, or a storage shelf for temporarily storing the article 2. The holder 21 at the transfer height H2 performs the holding operation of the article 2 or the releasing operation of the article 2. The transfer height H2 is set based on the height of the transfer area 4. In the example shown in FIG. 2, the transfer height H2 is lower than the reference height H1.

As shown in FIGS. 3 and 4, the article transferrer 1 includes an advancement-retraction driver M3 (e.g., an electric motor such as a servomotor) that advances and retracts the holder 21. To advance and retract herein refers to advancing and retracting an object relative to the reference portion in the article transferrer 1 described above. The advancement-retraction driver M3 thus advances and retracts the holder 21 relative to the body 20.

The article transferrer 1 includes an advancement-retraction device 24 that advances and retracts the holder 21. The advancement-retraction driver M3 activates the advancement-retraction device 24 to advance and retract the holder 21. The advancement-retraction device 24 advances and retracts the holder 21 with, for example, the holder 21 maintaining its orientation (or in other words, translates the holder 21 between a retracted position and an advancement position). The retracted position and the advancement position will be described later. The advancement-retraction device 24 may include, for example, a slide assembly (linear mover). In the present embodiment, the lifter 22 supports the holder 21 while allowing the holder 21 to be lifted and lowered, and the advancement-retraction device 24 supports the lifter 22 while allowing the lifter 22 to be advanced and retracted. The advancement-retraction device 24 advances and retracts the lifter 22 to advance and retract the holder 21 supported by the lifter 22. In the example shown in FIG. 3, the advancement-retraction device 24 advances and retracts the lifter 22 with the lifter 22 maintaining its orientation (or in other words, translates the lifter 22).

The advancement-retraction driver M3 moves the holder 21 in an advancement and retraction direction D, which may be parallel to or inclined to a horizontal plane. In the present embodiment, the advancement and retraction direction D is parallel to the horizontal plane. Being parallel to a plane herein is not limited to being parallel to the plane and may also include being slightly inclined to the plane. The advancement and retraction direction D is not limited to a direction parallel to the horizontal plane and may be a direction slightly inclined to the horizontal plane. In the examples shown in FIGS. 1 to 3, the advancement and retraction direction D is parallel to the width direction Y.

When the transport vehicle 100 travels along the travel path 40, the holder 21 is at the retracted position. The retracted position is a position adjacent to the reference portion described above in the article transferrer 1. In the present embodiment, the holder 21 as viewed vertically in the vertical direction Z overlaps the traveler 10 at the retracted position. Although the holder 21 is not shown in FIG. 1, the holder 21 holding an article 2 is at the retracted position in FIG. 1.

When the transport vehicle 100 (more specifically, the article transferrer 1) transfers an article 2 between the holder 21 and the transfer area 4 (to which the article 2 is transferred) at a position overlapping the travel path 40 as viewed in the vertical direction, the holder 21 is at the retracted position. When the transfer area 4 to which the article 2 is transferred is at a position shifted from the travel path 40 in the width direction Y as viewed in the vertical direction, the holder 21 is at the advancement position. The advancement position is a position opposite to the reference portion described above in the article transferrer 1. In the present embodiment, the holder 21 overlaps the transfer area 4 at the advancement position as viewed in the vertical direction. FIG. 3 shows the holder 21 at the advancement position.

The article transferrer 1 includes a controller 30 (refer to FIG. 4) that controls the advancement-retraction driver M3. In the present embodiment, the controller 30 further controls the travel driver M1, the lift driver M2, and the holder driver M4. The controller 30 includes, for example, an arithmetic processor such as a central processing unit (CPU) and a peripheral circuit such as a memory. The functions of the controller 30 are implemented by, for example, hardware such as an arithmetic processor and a program executable on the hardware operating in cooperation with each other. The controller 30 controls at least the advancement-retraction driver M3. A controller other than the controller 30 may control at least one of the travel driver M1, the lift driver M2, or the holder driver M4.

The controller 30 may be divided into multiple controllers that can communicate with one another. The controller 30 may be entirely included in a device (hereafter referred to as a main device) including a component to be controlled, such as the advancement-retraction driver M3, or entirely included in a device (hereafter referred to as an external device) that is external to the main device and can communicate with the main device. The controller 30 may be partially included in the main device and partially included in the external device. In the present embodiment, the main device is the transport vehicle 100.

The various technical features of the controller 30 described below are applicable to an operation method for the controller 30 and a program for causing a computer to function as the controller 30. The operation method, the program, and a recording medium (a computer-readable recording medium such as an optical disc or a flash memory) recording the program are also described herein. The program for causing a computer to function as the controller 30 is provided from, for example, a recording medium storing the program or through a communication network. The provided program is stored into a storage device that can be referred by the computer.

The controller 30 controls the travel driver M1 to cause the traveler 10 to travel along the travel path 40. The controller 30 controls the lift driver M2 to cause the lifter 22 to perform a lifting and lowering operation of lifting and lowering the holder 21. The lifting and lowering operation includes a lifting operation of lifting the holder 21 and a lowering operation of lowering the holder 21. In the present embodiment, in the lifting and lowering operation of the holder 21, the controller 30 controls the lift driver M2 to increase the speed of lifting and lowering the holder 21 gradually to a target speed, perform a constant-speed lifting and lowering operation of maintaining the speed of lifting and lowering the holder 21 at the target speed, and decrease the speed of lifting and lowering the holder 21 gradually from the target speed until the holder 21 stops. The controller 30 controls the advancement-retraction driver M3 to cause the advancement-retraction device 24 to perform an advancement and retraction operation of advancing and retracting the holder 21. The advancement and retraction operation includes an advancement operation of advancing the holder 21 and a retraction operation of retracting the holder 21. The controller 30 controls the holder driver M4 to cause the holder 21 to perform the holding operation and the releasing operation.

When the transport vehicle 100 (more specifically, the article transferrer 1) transfers an article 2 between the holder 21 and the transfer area 4 at a position shifted from the travel path 40 in the width direction Y as viewed in the vertical direction, the controller 30 controls the travel driver M1, the lift driver M2, the advancement-retraction driver M3, and the holder driver M4 to operate the transport vehicle 100 as below.

In transferring an article 2 from the holder 21 to the transfer area 4, the controller 30 causes the traveler 10 to perform a travel operation of causing the transport vehicle 100 to travel to the same position as the transfer area 4 in the travel direction X, with the holder 21 holding the article 2 at the reference height H1 and at the retracted position. The controller 30 then causes the advancement-retraction device 24 to perform the advancement operation of moving the holder 21 holding the article 2 from the retracted position to the advancement position, causes the lifter 22 to perform the lifting and lowering operation (lowering operation in this example) of lifting and lowering the holder 21 from the reference height H1 to the transfer height H2, and causes the holder 21 to perform the releasing operation of the article 2. The controller 30 causes the lifter 22 to perform the lifting and lowering operation (lifting operation in this example) of lifting and lowering the holder 21 holding no article 2 from the transfer height H2 to the reference height H1 and then causes the advancement-retraction device 24 to perform the retraction operation of retracting the holder 21 from the advancement position to the retracted position.

In transferring an article 2 from the transfer area 4 to the holder 21, the controller 30 causes the traveler 10 to perform the travel operation of causing the transport vehicle 100 to travel to the same position as the transfer area 4 in the travel direction X, with the holder 21 holding no article 2 being at the reference height H1 and at the retracted position. The controller 30 then causes the advancement-retraction device 24 to perform the advancement operation of moving the holder 21 holding no article 2 from the retracted position to the advancement position, causes the lifter 22 to perform the lifting and lowering operation (lowering operation in this example) of lifting and lowering the holder 21 from the reference height H1 to the transfer height H2, and causes the holder 21 to perform the holding operation of the article 2. The controller 30 causes the lifter 22 to perform the lifting and lowering operation (lifting operation in this example) of lifting and lowering the holder 21 holding the article 2 from the transfer height H2 to the reference height H1 and then causes the advancement-retraction device 24 to perform the retraction operation of retracting the holder 21 from the advancement position to the retracted position.

Although not described in detail, when the transport vehicle 100 (more specifically, the article transferrer 1) transfers an article 2 between the holder 21 and the transfer area 4 at a position overlapping the travel path 40 as viewed in the vertical direction, the controller 30 operates the transport vehicle 100 as described above, except that the advancement-retraction device 24 does not perform the advancement operation of the holder 21 or the retraction operation of the holder 21.

As described above, in transferring an article 2 between the holder 21 and the transfer area 4, the controller 30 causes the advancement-retraction device 24 to perform the advancement and retraction operation of advancing and retracting the holder 21. To reduce the vibration of the holder 21 or an article 2 held by the holder 21 due to the advancement and retraction operation of the holder 21, the controller 30 controls the advancement-retraction driver M3 as described below in the advancement and retraction operation of advancing or retracting the holder 21 by the advancement-retraction driver M3. The controller 30 may control the advancement-retraction driver M3 as described below in simply one of the advancement operation of advancing the holder 21 or the retraction operation of retracting the holder 21 but not in both these operations.

The controller 30 determines output command values based on a reference command pattern being a time-varying pattern of the command values indicating positions, speed, or acceleration which time-varying pattern involves a stepwise acceleration change over time in the advancement and retraction operation of advancing or retracting the holder 21 by the advancement-retraction driver M3. The output command values are each a moving average of command values indicated by the reference command pattern within a predetermined period. Acceleration includes deceleration (negative acceleration). The controller 30 controls the advancement-retraction driver M3 based on the output command values. Thus, although the acceleration changes stepwise with the reference command pattern, the speed of the holder 21 can be changed to allow acceleration of the holder 21 to change smoothly. In other words, the speed of the holder 21 can be changed to allow acceleration of the holder 21 to change smoothly without deriving, through calculation reflecting jerk (the rate of change in acceleration), the time-varying pattern of command values that allows acceleration to change smoothly.

The controller 30 determines, as the output command values, command values resulting from a moving average process performed on the reference command pattern. More specifically, the controller 30 determines, as the output command values, command values resulting from a moving average process performed on pieces of time series data in the reference command pattern within a predetermined period (moving average time frame). The moving average process may be, for example, an unweighted simple moving average process. The controller 30 obtains the reference command pattern from, for example, another controller such as a host controller or by referring to a storage.

The reference command pattern may be any of a time-varying pattern of positional command values (hereafter referred to as a reference positional command pattern) that causes acceleration to change stepwise over time, a time-varying pattern of speed command values (hereafter referred to as a reference speed command pattern) that causes acceleration to change stepwise over time, or a time-varying pattern of acceleration command values (hereafter referred to as a reference acceleration command pattern) that causes acceleration to change stepwise over time. When the reference command pattern is a reference positional command pattern, the output command values are positional command values. When the reference command pattern is a reference speed command pattern, the output command values are speed command values. When the reference command pattern is a reference acceleration command pattern, the output command values are acceleration command values.

When the output command values are positional command values, the controller 30 controls the advancement-retraction driver M3 through position control based on the output command values. When the output command values are speed command values, the controller 30 controls the advancement-retraction driver M3 through speed control based on the output command values. When the output command values are acceleration command values, the controller 30 controls the advancement-retraction driver M3 through acceleration control based on the output command values. In controlling the advancement-retraction driver M3 based on the output command values, the controller 30 may control the advancement-retraction driver M3 based on command values being differentiated or integrated output command values. When the output command values are speed command values, for example, the controller 30 may control the advancement-retraction driver M3 through position control based on positional command values generated by integrating the output command values.

The controller 30 controls the advancement-retraction driver M3 based on the output command values through, for example, feedback control. In the feedback control, the controller 30 generates a drive command based on deviation between a feedback value and a command value (an output command value or a command value being differentiated or integrated output command values) and controls the advancement-retraction driver M3 to output a driving force (e.g., torque) corresponding to the drive command. The feedback value is detected by, for example, a detector (e.g., an encoder) included in the advancement-retraction driver M3. The controller 30 may control the advancement-retraction driver M3 based on the output command values through feedforward control or combination of feedback control and feedforward control.

The controller 30 may control the advancement-retraction driver M3 based on the command values indicated by the reference command pattern under a specific condition. The details of control performed by the controller 30 that controls the advancement-retraction driver M3 based on the command values indicated by the reference command pattern are the same as described above for the controller 30 that controls the advancement-retraction driver M3 based on the output command values (moving averages of the reference command pattern) being replaced with the command values indicated by the reference command pattern and thus are not described in detail.

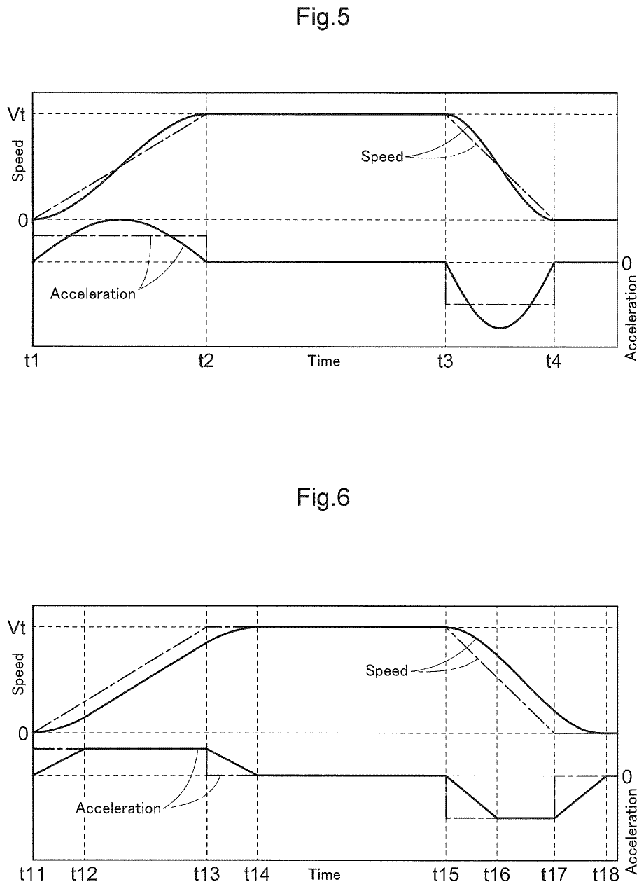

In the advancement and retraction operation of the holder 21 in the present embodiment, the controller 30 controls the advancement-retraction driver M3 to increase the speed of the holder 21 gradually toward the target speed Vt (refer to FIGS. 5 and 6), maintain the speed of the holder 21 at the target speed Vt, and decrease the speed of the holder 21 gradually from the target speed Vt until the holder 21 stops. In the example shown in FIG. 5, the speed of the holder 21 increases gradually toward the target speed Vt in a period from time t1 to time t2, is maintained at the target speed Vt in a period from time t2 to time t3, and decreases gradually from the target speed Vt in a period from time t3 to time t4. In the present embodiment, the reference command pattern is a reference speed command pattern, and the speed indicated by the dot-dash lines in FIGS. 5 and 6 represents the reference command pattern (reference speed command pattern) when the speed of the holder 21 changes as described above. Acceleration indicated by the dot-dash lines in FIGS. 5 and 6 represents the transition of acceleration (more specifically, the first-order derivative of the speed indicated by the reference speed command pattern) corresponding to the reference speed command pattern over time.

The speed and the acceleration indicated by the solid lines in FIG. 5 represent the transition of speed and acceleration over time after a sinusoidal process that transforms stepwise changes of acceleration into sinusoidal changes of acceleration. The sinusoidal process can thus change the speed of the holder 21 to allow the acceleration of the holder 21 to change smoothly. However, as shown in FIG. 5, the maximum value (in the absolute value; the same applies hereafter) of the acceleration of the holder 21 exceeds, or more specifically, is π/2 times, the maximum value of the acceleration corresponding to the reference speed command pattern indicated by the dot-dash lines in FIG. 5. Such an increase in the maximum value of the acceleration of the holder 21 may, for example, adversely affect an article 2 held by the holder 21. Thus, this technique may have limited applications.

In contrast, the controller 30 controls the advancement-retraction driver M3 based on the output command values being moving averages of the command values indicated by the reference command pattern (a reference speed command pattern in the present embodiment). Thus, as shown in FIG. 6, the speed of the holder 21 can be changed to allow the acceleration of the holder 21 to change smoothly without the maximum value of the acceleration of the holder 21 exceeding the maximum value of the acceleration corresponding to the reference speed command pattern indicated by the dot-dash lines in FIG. 6. In FIG. 6, the speed indicated by the solid line represents the transition of the output command values (speed command values in this example) being moving averages of the reference command pattern over time, and acceleration indicated by the solid line represents the transition of acceleration corresponding to the speed indicated by the solid line over time.

Times t11, t13, t15, and t17 in FIG. 6 correspond to times t1, t2, t3, and t4 in FIG. 5. In FIG. 6, the period from time t11 to time t12, the period from time t13 to time t14, the period from time t15 to time t16, and the period from time t17 to time t18 each have the same duration as the predetermined period (moving average time frame) for the moving average. As shown in FIG. 6, in controlling the advancement-retraction driver M3 based on the output command values being moving averages of the reference command pattern, the time for the holder 21 to reach a target position (the retracted position or the advancement position), or in other words, the time taken for the advancement and retraction operation of the holder 21, is longer by the length of the predetermined period than in controlling the advancement-retraction driver M3 based on the command values indicated by the reference command pattern. In the example shown in FIG. 6, the time taken for the advancement and retraction operation of the holder 21 is extended from the time from time t11 to time t17 to the time from time t11 to time t18. When the predetermined period is longer, the acceleration of the holder 21 changes more smoothly. However, as described above, the time taken for the advancement and retraction operation of the holder 21 is also longer accordingly.

The controller 30 may not change the length of the predetermined period, or the controller 30 may change the length of the predetermined period as described below to reflect the time taken for the advancement and retraction operation of the holder 21 being longer by the length of the predetermined period as described above. The length of the predetermined period may be changed to zero (or in other words, the advancement-retraction driver M3 may be controlled based on the command values indicated by the reference command pattern).

For example, the controller 30 may set the predetermined period to be longer for the holder 21 holding an article 2 than for the holder 21 holding no article 2. In this case, the article transferrer 1 may include, as shown in FIG. 4, a determiner 31 that determines whether the holder 21 is holding an article 2, and the controller 30 may change the length of the predetermined period as described above based on the determination result from the determiner 31. The determiner 31 and a weight determiner 32 (described later) may be implemented by, for example, the controller 30 (more specifically, an arithmetic processor) executing a program. The controller 30, the determiner 31, and the weight determiner 32 (described later) shown in FIG. 4 are distinguished at least logically or conceptually, and may not be distinguished physically. For example, the determiner 31 and the weight determiner 32 may be a common single determiner.

In transferring an article 2 from the holder 21 to the transfer area 4 (hereafter referred to as drop-off transfer), the advancement operation of advancing the holder 21 is performed with the holder 21 holding an article 2, and the retraction operation of retracting the holder 21 is performed with the holder 21 holding no article 2. In transferring an article 2 from the transfer area 4 to the holder 21 (hereafter referred to as pickup transfer), the advancement operation of advancing the holder 21 is performed with the holder 21 holding no article 2, and the retraction operation of retracting the holder 21 is performed with the holder 21 holding an article 2. Thus, the determiner 31 can determine whether the holder 21 is holding an article 2 in the advancement and retraction operation (the advancement operation or the retraction operation) based on, for example, whether the drop-off transfer or the pickup transfer is performed. When the controller 30 causes the transport vehicle 100 to transport an article 2 in response to a command from another controller such as a host controller, the determiner 31 can determine whether the drop-off transfer or the pickup transfer is performed based on the command.

The determiner 31 is not limited to using the determination method described above. For example, the determiner 31 may determine whether the holder 21 is holding an article 2 based on an indicator (e.g., output torque or a current value for the lift driver M2 being a motor) associated with the driving force of the lift driver M2 in the lifting and lowering operation. The determiner 31 may determine whether the holder 21 is holding an article 2 based on information detected by a sensor (e.g., a presence sensor for detecting the presence of an article 2 or a weight sensor for detecting the weight of an article 2) installed on the holder 21.

In the structure in which the controller 30 sets the predetermined period to be longer for the holder 21 holding an article 2 than for the holder 21 holding no article 2 as described above, the controller 30 may set the predetermined period to zero for the holder 21 holding no article 2. In this case, the controller 30 controls the advancement-retraction driver M3 based on the output command values in the advancement and retraction operation with the holder 21 holding an article 2 and controls the advancement-retraction driver M3 based on the command values indicated by the reference command pattern in the advancement and retraction operation with the holder 21 holding no article 2.

The vibration pattern of the holder 21 or an article 2 held by the holder 21 may vary depending on the weight of the article 2. Thus, the length of the predetermined period that can reduce vibration effectively may vary depending on the weight of the article 2. To reflect the above, the controller 30 can change the predetermined period (more specifically, change the length of the predetermined period; the same applies hereafter) based on the weight of an article 2 held by the holder 21. In this case, as shown in FIG. 4, the article transferrer 1 includes the weight determiner 32 that determines the weight of an article 2 held by the holder 21, and the controller 30 may change the predetermined period as described above based on the determination result from the weight determiner 32. When the article 2 is a container for containing substrates such as semiconductor wafers, the weight of the article 2 may vary depending on the number of substrates contained in the article 2. For example, the weight determiner 32 may determine the weight of the article 2 held by the holder 21 while the lift driver M2 is performing the lifting and lowering operation of the holder 21.

When the controller 30 that causes the transport vehicle 100 to transport an article 2 in response to a command from another controller, such as a host controller, can obtain information about the weight of the article 2 based on the command, the weight determiner 32 may determine the weight of the article 2 held by the holder 21 based on the command. In the same manner as the determiner 31 that performs the determination as described above, the weight determiner 32 may determine the weight of an article 2 held by the holder 21 based on an indicator associated with the driving force of the lift driver M2 in the lifting and lowering operation or based on information detected by the weight sensor installed on the holder 21.

In one example, appropriate predetermined periods may be obtained for weight categories of the articles 2 in advance through, for example, a test, and the controller 30 may change a predetermined period to another period for a weight category corresponding to the weight of an article 2 held by the holder 21. In another example, the controller 30 may simply set the predetermined period to be longer in a stepwise or sequential manner as the weight of the article 2 held by the holder 21 increases. The property of the article 2 that serves as a reference in changing the predetermined period is not limited to the weight of the article 2. The controller 30 may change the predetermined period based on the property of the article 2 held by the holder 21 other than the weight (e.g., vibration tolerance).

When the predetermined period is changed in the advancement and retraction operation of the holder 21, the output command values are discontinuous before and after changing the length of the predetermined period. This may destabilize the advancement and retraction operation of the holder 21. In response to the above, the controller 30 may change the predetermined period in a period in which no advancement and retraction operation is performed. In the present embodiment, the period in which no advancement and retraction operation is performed includes a period in which the lift driver M2 performs the lifting and lowering operation of the holder 21, a period in which the holder 21 performs the holding operation, and a period in which the holder 21 performs the releasing operation. Thus, the controller 30 can change the predetermined period in the lifting and lowering operation of the holder 21 performed by the lift driver M2, in the holding operation performed by the holder 21, or in the releasing operation performed by the holder 21. The controller 30 may change the predetermined period while the lift driver M2 is performing the lifting and lowering operation of the holder 21. In other words, the controller 30 may not change the predetermined period while the holder 21 is performing the holding operation or the releasing operation.

In the present embodiment, the drop-off transfer includes the advancement operation of the holder 21, the lowering operation of the holder 21, the releasing operation performed by the holder 21, the lifting operation of the holder 21, and the retraction operation of the holder 21 performed in this order. In this case, the predetermined period can be changed to be shorter in the lowering operation of the holder 21, in the releasing operation performed by the holder 21, or in the lifting operation of the holder 21. Thus, the predetermined period can be longer for the holder 21 holding an article 2 than for the holder 21 holding no article 2. To change the predetermined period in the lowering operation of the holder 21 in the drop-off transfer, the predetermined period may be changed, for example, while the holder 21 is being lowered in the constant-speed lifting and lowering operation described above.

In the present embodiment, the pickup transfer includes the advancement operation of the holder 21, the lowering operation of the holder 21, the holding operation performed by the holder 21, the lifting operation of the holder 21, and the retraction operation of the holder 21 performed in this order. In this case, the predetermined period can be changed to be longer in the lowering operation of the holder 21, in the holding operation performed by the holder 21, or in the lifting operation of the holder 21. Thus, the predetermined period can be longer for the holder 21 holding the article 2 than for the holder 21 holding no article 2. To change the predetermined period in the lifting operation of the holder 21 in the pickup transfer, the predetermined period may be changed, for example, while the holder 21 is being lifted in the constant-speed lifting and lowering operation described above after the article 2 left the transfer area 4 as the holder 21 rises.

### Other Embodiments

(1) In the above embodiment, the lifter 22 supports the holder 21 while allowing the holder 21 to be lifted and lowered, and the advancement-retraction device 24 supports the lifter 22 while allowing the lifter 22 to be advanced and retracted. Embodiments of the disclosure are not limited to this structure. The advancement-retraction device 24 may support the holder 21 while allowing the holder 21 to be advanced and retracted, and the lifter 22 may support the advancement-retraction device 24 while allowing the advancement-retraction device 24 to be lifted and lowered. In this case, the lifter 22 lifts and lowers the advancement-retraction device 24 to lift and lower the holder 21 supported by the advancement-retraction device 24.
(2) In the above embodiment, the article transferrer 1 includes the lift driver M2 that lifts and lowers the holder 21. Embodiments of the disclosure are not limited to this structure. The article transferrer 1 may include no lift driver M2. In other words, the article transferrer 1 may include no lifter 22. In this case, for example, a device disposed in the transfer area 4 to which an article 2 is transferred includes a device for lifting and lowering the article 2.
(3) In the above embodiment, the transport vehicle 100 including the article transferrer 1 is a ceiling-hung transport vehicle that travels along the travel path 40 defined along the ceiling 3. Embodiments of the disclosure are not limited to this structure. A transport vehicle 100 with another structure may include the article transferrer 1. FIG. 7 shows a transport vehicle 100 that is a stacker crane including an article transferrer 1. In FIG. 7, the same reference signs denote the components having the same functions as those in the transport vehicle 100 in the above embodiment.

The transport vehicle 100 shown in FIG. 7 includes a traveler 10 that travels along a travel rail 41 disposed on the floor surface, masts 12 standing upright on the traveler 10, and a lift mount 13 that is lifted and lowered along the masts 12. A holder 21 is supported by the lift mount 13. The traveler 10 driven by a travel driver M1 travels along a travel path 40 with the upper ends of the masts 12 being guided by a guide rail 42 disposed adjacent to the ceiling. A lifter 22 lifts and lowers the lift mount 13 along the masts 12, and a lift driver M2 activates the lifter 22 to lift and lower the lift mount 13 and the holder 21 supported by the lift mount 13.

In the example shown in FIG. 7, the holder 21 in the lower direction Z2 holds an article 2. More specifically, the holder 21 in the lower direction Z2 supports the bottom of the article 2 and holds the article 2. An advancement-retraction device 24 advances and retracts the holder 21 relative to the lift mount 13. An advancement-retraction driver M3 (not shown in FIG. 7) activates the advancement-retraction device 24 to advance and retract the holder 21 relative to the lift mount 13. In the example shown in FIG. 7, a driver corresponding to the holder driver M4 in the above embodiment is eliminated. In the example shown in FIG. 7, a transfer area 4 is, for example, a shelf in a storage rack for storing the articles 2 with multiple shelves arranged in the vertical direction Z.

In drop-off transfer, the advancement operation of the holder 21, the lowering operation of the holder 21, and the retraction operation of the holder 21 are performed in this order. In this case, the predetermined period is changed to be shorter in the lowering operation of the holder 21. Thus, the predetermined period can be longer for the holder 21 holding the article 2 than for the holder 21 holding no article 2. In pickup transfer, the advancement operation of the holder 21, the lifting operation of the holder 21, and the retraction operation of the holder 21 are performed in this order. In this case, the predetermined period is changed to be longer in the lifting operation of the holder 21. Thus, the predetermined period can be longer for the holder 21 holding the article 2 than for the holder 21 holding no article 2.

The transport vehicle 100 including the article transferrer 1 is not limited to the structure that travels along the travel rail 41, or a ceiling-hung transport vehicle, a stacker crane, or another tracked transport vehicle. The transport vehicle 100 may be a trackless transport vehicle such as an automated guided vehicle (AGV) or an autonomous mobile robot (AMR). For the transport vehicle 100 that is a trackless transport vehicle, the transport vehicle 100 travels not along a travel path 40 physically defined with, for example, a travel rail but along a travel path 40 defined virtually. For example, multiple detectable members, such as two-dimensional codes or radio frequency (RF) tags, are installed on the floor surface to define a virtual travel path 40 that connects the multiple detectable members. Such detectable members may not be installed on the floor surface, and the virtual travel path 40 may be a route calculated based on the recognition result of the surrounding environment.
(4) In the above embodiment, the transport vehicle 100 includes the article transferrer 1. Embodiments of the disclosure are not limited to this structure. The article transferrer 1 may be fixed to, for example, the floor.
(5) The structure described in each of the above embodiments may be combined with any other structures described in the other embodiments unless any contradiction arises. This also applies to combinations of the embodiments described as other embodiments. The embodiments described herein are merely illustrative in all aspects and may be modified variously as appropriate without departing from the spirit and scope of the disclosure.

### Overview of Embodiment

The embodiments of the article transferrer described above are outlined below.

An article transferrer includes a holder that holds an article, an advancement-retraction driver that advances and retracts the holder, and a controller that controls the advancement-retraction driver. The controller controls the advancement-retraction driver based on an output command value in an advancement and retraction operation of advancing or retracting the holder by the advancement-retraction driver. The output command value is determined based on a reference command pattern being a time-varying pattern of command values indicating positions, speed, or acceleration which time-varying pattern involves a stepwise acceleration change over time. The output command value is a moving average, within a predetermined period, of the command values indicated by the reference command pattern.

This structure can reduce the change of acceleration (jerk) of the holder in the advancement and retraction operation of the holder compared with a structure that controls the advancement-retraction driver based on the command values indicated by the reference command pattern. This can reduce the change of acceleration acting on the article held by the holder. This structure can thus easily reduce the vibration of the holder or the article held by the holder due to the advancement and retraction operation of the holder.

The article transferrer may further include a determiner that determines whether the holder is holding the article. The controller may set the predetermined period to be longer in response to the determiner determining that the holder is holding the article as compared to a case of the determiner determining that the holder is holding no article.

In this structure, the predetermined period is longer for the holder holding an article to reduce the change of acceleration acting on the article. This can reduce the vibration of the article. For the holder holding no article, the predetermined period is shorter to prevent the time taken for the advancement and retraction operation of the holder from being longer. Thus, this structure can reduce the vibration of an article held by the holder and reduce the likelihood of the time taken for the advancement and retraction operation of the holder being longer.

The article transferrer may further include a determiner that determines whether the holder is holding the article. The controller may, during the advancement and retraction operation with the determiner determining that the holder is holding the article, control the advancement-retraction driver based on the output command value. The controller may, during the advancement and retraction operation with the determiner determining that the holder is holding no article, control the advancement-retraction driver based on the command values indicated by the reference command pattern.

In this structure, for the holder holding an article, the advancement-retraction driver is controlled based on the output command value being a moving average of the command values indicated by the reference command pattern. This can reduce the change of acceleration acting on the article and vibration of the article. When the holder is holding no article, the advancement-retraction driver is controlled based on the command value indicated by the reference command pattern without using the moving average. Thus, the time taken for the advancement and retraction operation of the holder can be shorter than the time with the moving average. Thus, this structure can reduce the vibration of an article held by the holder and reduce the likelihood of the time taken for the advancement and retraction operation of the holder being longer.

The article transferrer may further include a weight determiner that determines a weight of the article held by the holder. The controller may change the predetermined period based on the weight of the article held by the holder.

This structure can set an appropriate predetermined period based on the weight of the article held by the holder.

The article transferrer may further include a lift driver that lifts and lowers the holder. The advancement-retraction driver may advance and retract the holder in an advancement and retraction direction parallel to a horizontal plane. The controller may change the predetermined period in a lifting and lowering operation of the holder performed by the lift driver.

In this structure, the predetermined period can be changed in a period in which the lift driver lifts and lowers the holder. The predetermined period is thus changed in the lifting and lowering operation of the holder by the lift driver and is not changed in the advancement and retraction operation of the holder. This facilitates a stable advancement and retraction operation of the holder.

The article transferrer according to one or more embodiments of the disclosure may produce at least one of the effects described above.

What is claimed is:

1. An article transferrer, comprising:
a holder configured to hold an article;
an advancement-retraction driver configured to advance and retract the holder; and
a controller configured to control the advancement-retraction driver, and
wherein the controller is configured to control the advancement-retraction driver based on an output command value in an advancement and retraction operation of advancing or retracting the holder by the advancement-retraction driver, wherein the output command value is determined based on a reference command pattern being a time-varying pattern of command values indicating positions, speed, or acceleration which time-varying pattern involves a stepwise acceleration change over time, and wherein the output command value is a moving average, within a predetermined period, of the command values indicated by the reference command pattern.

2. The article transferrer according to claim 1, further comprising:
a determiner configured to determine whether the holder is holding the article, and
wherein the controller sets the predetermined period to be longer in response to the determiner determining that the holder is holding the article as compared to a case of the determiner determining that the holder is holding no article.

3. The article transferrer according to claim 1, further comprising:
a determiner configured to determine whether the holder is holding the article, and
wherein during the advancement and retraction operation with the determiner determining that the holder is holding the article, the controller controls the advancement-retraction driver based on the output command value, and
wherein during the advancement and retraction operation with the determiner determining that the holder is holding no article, the controller controls the advancement-retraction driver based on the command values indicated by the reference command pattern.

4. The article transferrer according to claim 1, further comprising:
a weight determiner configured to determine a weight of the article held by the holder, and
wherein the controller changes the predetermined period based on the weight of the article held by the holder.

5. The article transferrer according to claim 2, further comprising:
a lift driver configured to lift and lower the holder, and
wherein the advancement-retraction driver advances and retracts the holder in an advancement and retraction direction parallel to a horizontal plane, and
wherein the controller changes the predetermined period in a lifting and lowering operation of the holder performed by the lift driver.
